(19) United States
(12) Patent Application Publication
(10) Pub. No.: US 2026/0353870 A1
(43) Pub. Date: Nov. 5, 2026

(54) SEMICONDUCTOR OPTICAL ELEMENT ARRAY

(71) Applicants: DAI NIPPON PRINTING CO., LTD., Tokyo-to (JP); SOPHIA SCHOOL CORPORATION, Tokyo-to (JP)

(72) Inventors: Satoshi YUSA, Tokyo-to (JP); Katsumi KISHINO, Akiruno-shi (JP)

(73) Assignees: DAI NIPPON PRINTING CO., LTD., Tokyo-to (JP); SOPHIA SCHOOL CORPORATION, Tokyo-to (JP)

(21) Appl. No.: 19/099,928

(22) PCT Filed: Aug. 2, 2023
(86) PCT No.: PCT/JP2023/028233

§ 371 Date: Dec. 3, 2025

(30) Foreign Application Priority Data
Aug. 2, 2022 (JP) 2022-123352

(51) Int. Cl. H10H 20/819; H10H 20/825; H10H 29/34

(52) U.S. Cl. CPC H10H 20/819; H10H 20/825; H10H 29/34

(57) ABSTRACT

A semiconductor optical element array including: a semiconductor substrate, a mask layer disposed on a main surface of the semiconductor substrate and including an opening, a nano-column that extends in a thickness direction from the semiconductor substrate through the opening, and is a columnar crystal of a group-III nitride semiconductor, a light-emitting layer disposed at a tip of the nano-column, and a covering semiconductor layer covering the light-emitting layer and including a semiconductor, wherein the semiconductor optical element array includes a pixel including a plurality of the nano-columns; and in the pixel, a size of the nano-column either increases in a stepwise manner or continuously, or decreases in a stepwise manner or continuously, from center toward outer periphery.

### TECHNICAL FIELD

The present disclosure relates to a semiconductor optical element array.

### BACKGROUND ART

In recent years, group-III nitride semiconductors such as gallium nitride (GaN) have attracted attention as semiconductor materials useful for light-emitting elements such as light-emitting diodes and laser diodes. The light-emitting element is manufactured by forming a stacked structure of a group-III nitride semiconductor on a substrate using a crystal growth technique such as a metal organic chemical vapor deposition (MOCVD) method or a molecular beam epitaxy (MBE) method.

For example, Patent Literature 1 discloses a semiconductor optical element array provided with a fine columnar crystal including a group-III nitride semiconductor grown from a semiconductor substrate through an opening disposed in a mask pattern. One object of this technology is to control the position and the shape of the fine columnar crystal formed on a substrate with high accuracy.

### CITATION LIST

### Patent Documents

Patent Document 1: International Publication WO2010/023921

### SUMMARY

### Technical Problem

The semiconductor optical element array is used for, for example, a light-emitting element. From the viewpoint of improving the performance e of a light-emitting element, it is desired to improve the optical characteristics of the semiconductor optical element array. The present disclosure has been made in view of the above circumstances, and a main object thereof is to provide a semiconductor optical element array with excellent optical characteristics.

### Solution to Problem

The present disclosure provides a semiconductor optical element array including a semiconductor substrate, a mask layer disposed on a main surface of the semiconductor substrate and including an opening, a nano-column that extends in a thickness direction from the semiconductor substrate through the opening, and is a columnar crystal of a group-III nitride semiconductor, a light-emitting layer disposed at a tip of the nano-column, and a covering semiconductor layer covering the light-emitting layer and including a semiconductor, wherein the semiconductor optical element array includes a pixel including a plurality of the nano-columns, and in the pixel, a size of the nano-column either increases in a stepwise manner or continuously, or decreases in a stepwise manner or continuously, from center toward outer periphery.

### Advantageous Effects

The semiconductor optical element array in the present disclosure exhibits an effect of having excellent optical characteristics.

### BRIEF DESCRIPTION OF DRAWINGS

FIG. 1 is a schematic cross-sectional view illustrating an example of a semiconductor optical element array in the present disclosure.

FIG. 2 is a schematic plan view illustrating an example of a mask layer and a nano-column in the present disclosure.

FIG. 3 is a schematic plan view illustrating an example of a pixel in the present disclosure.

FIG. 4 is a schematic plan view illustrating an example of a pixel in the present disclosure.

FIG. 5 is an explanatory diagram for explaining a pixel in the present disclosure.

FIG. 6 is an explanatory diagram for explaining a pixel in the present disclosure.

FIG. 7 is a schematic cross-sectional view illustrating an example of a nano-column in the present disclosure.

FIG. 8 is a schematic plan view illustrating an example of a pixel in the present disclosure.

FIG. 9 is a schematic perspective view illustrating an example of a semiconductor optical element array in the present disclosure.

FIG. 10 is a schematic perspective view illustrating an example of a method for producing the semiconductor optical element array in the present disclosure.

FIG. 11 is an explanatory diagram for explaining pixels used in Comparative Example 1 and Examples 1 and 2.

FIG. 12 is an emission spectrum of pixels obtained in Comparative Example 1 and Examples 1 and 2.

FIG. 13 is an explanatory diagram for explaining pixels used in Comparative Example 2 and Examples 3 and 4.

FIG. 14 is an emission spectrum of pixels obtained in Comparative Example 2 and Examples 3 and 4.

### DESCRIPTION OF EMBODIMENTS

Hereinafter, a semiconductor optical element array in the present disclosure will be described in detail. In order to facilitate understanding, the size and shape of each part are appropriately exaggerated in each of the drawings described below. Further, in each drawing, hatching or reference numerals may be omitted for convenience. In the present disclosure, “another member is disposed on a surface (main surface) of one member” includes both a case in which another member is disposed so as to be in contact with a surface (main surface) of one member, and a case in which another member is disposed above a surface (main surface) of one member interposing another member.

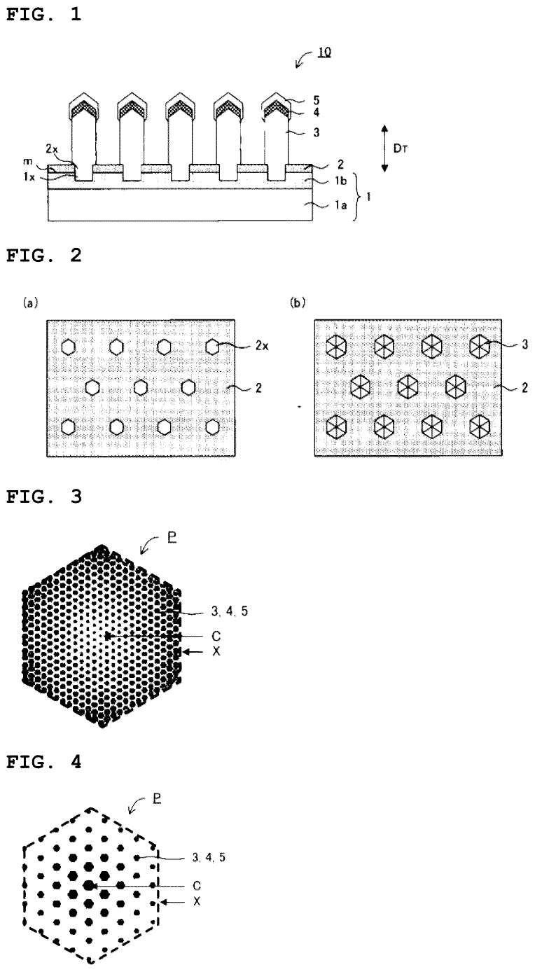

FIG. 1 is a schematic cross-sectional view illustrating an example of a semiconductor optical element array in the present disclosure. The semiconductor optical element array 10 illustrated in FIG. 1 includes a semiconductor substrate 1, a mask layer 2, a nano-column 3, a light-emitting layer 4, and a covering semiconductor layer 5. The semiconductor substrate 1 includes a base substrate 1a and a semiconductor layer 1b.

The mask layer 2 is disposed on the main surface m of the semiconductor substrate 1 (semiconductor layer 1b) and includes an opening 2x. The nano-column 3 extends from the semiconductor substrate 1 (semiconductor layer 1b) to the thickness direction Dr through the opening 2x of the mask layer 2, and is a columnar crystal of a group-III nitride semiconductor. The light-emitting layer 4 is disposed at the tip of the nano-column 3. The covering semiconductor layer 5 covers at least a part of the light-emitting layer 4 and includes a semiconductor.

FIG. 2 is a schematic plan view illustrating an example of a mask layer and a nano-column in the present disclosure. As shown in FIG. 2(a), the mask layer 2 includes a patterned opening 2x. The crystal of the group-III nitride semiconductor is epitaxially grown through the opening 2x. Thus, the nano-column 3 as shown in FIG. 1 and FIG. 2(b) is obtained.

The semiconductor optical element array in the present disclosure includes a pixel including a plurality of nano-columns. Specifically, one pixel is configured by arranging a plurality of nano-columns in a pattern shape. In each of the nano-columns, the light-emitting layer and the covering semiconductor layer described above are usually disposed. FIG. 3 and FIG. 4 are schematic plan views illustrating an example of pixels in the present disclosure, respectively. As shown in FIG. 3 and FIG. 4, the pixel P includes a plurality of nano-columns 3. In the pixel P shown in FIG. 3, the size of the nano-column 3 continuously increases from the center C toward the outer periphery X. On the other hand, in the pixel P shown in FIG. 4, the size of the nano-column 3 continuously decreases from the center C toward the outer periphery x.

According to the present disclosure, in the pixel including a plurality of nano-columns, the size of the nano-column either increases in a stepwise manner or continuously, or decreases in a stepwise manner or continuously, from center toward outer periphery, and thus the semiconductor optical element array may have excellent optical characteristics. Here, as described in Patent Document 1, the light emission characteristics of the light emitted from the light-emitting layer change according to the size of the nano-column. Specifically, the peak wavelength of the light emitted from the light-emitting layer is shifted to the longer wavelength side as the size of the nano-column is larger, and is shifted to the shorter wavelength side as the size of the nano-column is smaller.

Therefore, it is assumed that a pixel including a plurality of nano-columns whose size is uneven is inferior in monochromaticity to a pixel including a plurality of nano-columns whose size is uniform. However, when the size of the nano-column was changed from the center of the pixel toward the outer periphery of the pixel, a decrease in the monochromaticity was not confirmed at least in the vicinity of the center of the pixel. Further surprisingly, when the size of the nano-column was changed from the center of the pixel toward the outer periphery of the pixel, improvement of the emission intensity was confirmed at least in the vicinity of the center of the pixel. Although the reason is not completely clear, it is presumed that the nano-columns disposed near the outer periphery of the pixel exhibit a function such as a lens or a reflector, so that the light extraction efficiency is improved in the vicinity of the center of the pixel.

### 1. Pixel

A pixel in the present disclosure includes a plurality of nano-columns. Details of the nano-column will be described in “2. Nano-column” later. In addition, in the present disclosure, the size of the nano-column either increases in a stepwise manner or continuously, or decreases in a stepwise manner or continuously, from the center of the pixel toward the outer periphery of the pixel.

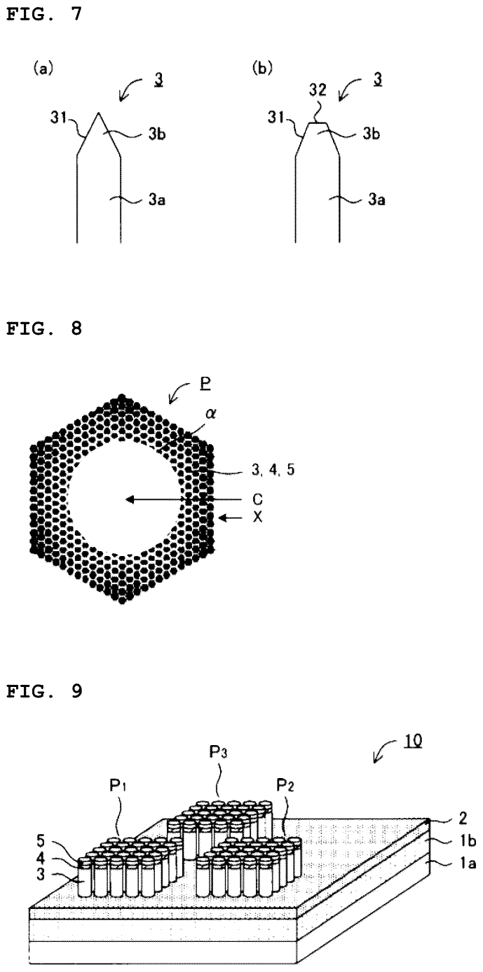

In the present disclosure, the center of the pixel refers to a centroid point of a plan view shape in which a pixel is viewed in a plan view along a thickness direction. On the other hand, the outer periphery of the pixel refers to an outer periphery of a plan view shape in which a pixel is viewed in a plan view along the thickness direction. The “size of the nano-column” refers to the size of the columnar portion of the nano-column (the columnar portion 3a illustrated in FIG. 7 described later). The size of the columnar portion refers to the length of the straight line passing through the center of gravity point (center) of the plan view shape in which the columnar portion is viewed in a plan view along the thickness direction and having the longest distance between the intersection points among the straight lines intersecting the columnar portion at two points.

The size of the nano-column in the center of the pixel is, for example, 10 nm or more and 1000 nm or less. The “nano-column in the center of the pixel” refers to the nano-column when the nano-column is present in the center of the pixel when the pixel is viewed in a plan view along the thickness direction, and refers to the nano-column closest to the center of the pixel when no nano-column is present in the center of the pixel. The size of the nano-column may be, for example, 700 nm or less, may be 650 nm or less, and may be 600 nm or less. By setting the size of the nano-column to 700 nm or less, the occurrence of threading dislocations is easily suppressed.

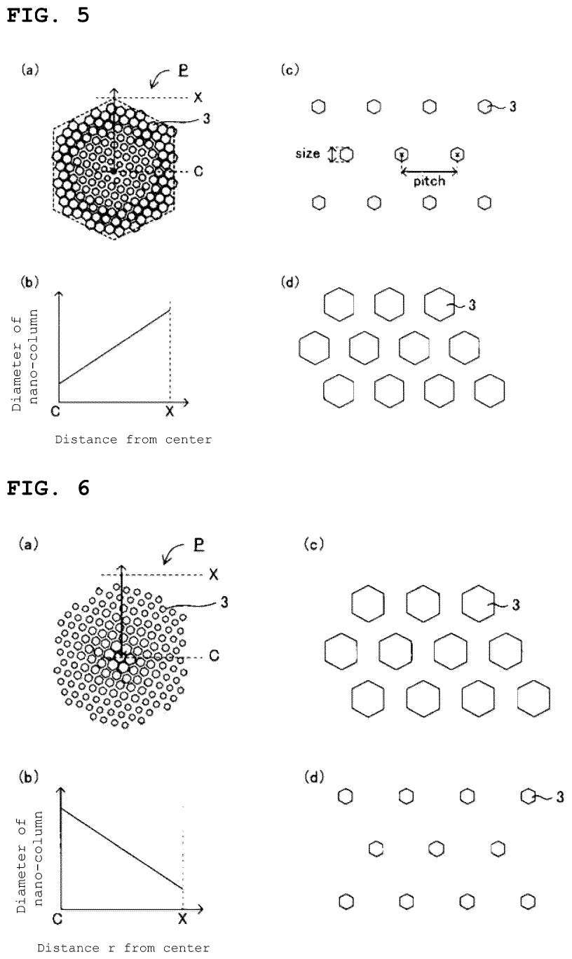

In the present disclosure, the size of the nano-column may increase in a stepwise manner or continuously from the center of the pixel toward the outer periphery of the pixel. This case will be described with reference to FIG. 5. In the pixel P shown in FIG. 5(a), the size of the nano-column 3 continuously increases from the center C toward the outer periphery X. In the pixel P shown in FIG. 5(a), the size of the nano-column 3 changes concentrically from the center C toward the outer periphery X. As shown in FIG. 5(b), the size of the nano-column may linearly increase from the center C toward the outer periphery X. On the other hand, although not shown in drawings, the size of the nano-column may increase in a curved manner (for example, in a n-function manner) from the center C toward the outer periphery X.

FIG. 5(c) shows the nano-column 3 in the vicinity of the center of the pixel, and FIG. 5(d) shows the nano-column 3 in the vicinity of the outer periphery of the pixel. Let S₁ be the size of the nano-column in the center of the pixel, and S₂ be the size of the nano-column in the outer periphery of the pixel. The “nano-column in the center of the pixel” is as described above. On the other hand, the “nano-column in the outer periphery of the pixel” refers to a nano-column configuring the outer periphery of the pixel when the pixel is viewed in a plan view along the thickness direction.

S₁ is, for example, 10 nm or more, may be 20 nm or more, and may be 30 nm or more. On the other hand, S₁ is, for example, 300 nm or less, may be 200 nm or less, and may be 100 nm or less. Further, S₂ is not particularly limited as long as it is larger than S₁, but may be, for example, 20 nm or more, may be 50 nm or more, or may be 100 nm or more. Meanwhile, S₂ is, for example, 1000 nm or less, may be 500 nm or less, and may be 300 nm or less. Also, the ratio of S₂ to S₁ (S₂/S₁) is, for example, 1.5 or more and 6.0 or less, and may be 2.0 or more and 4.0 or less.

Further, in the present disclosure, the size of the nano-column may increase in a stepwise manner from the center of the pixel toward the outer periphery of the pixel. In this case, the size of the nano-column may increase in two or more stages, may increase in five or more stages, and may increase in ten or more stages, from the center of the pixel toward the outer periphery of the pixel.

On the other hand, in the present disclosure, the size of the nano-column may decrease in a stepwise manner or continuously from the center of the pixel toward the outer periphery of the pixel. This case will be described with reference to FIG. 6. In the pixel P shown in FIG. 6(a), the size of the nano-column 3 continuously decreases from the center C toward the outer periphery X. In the pixel P shown in FIG. 6(a), the size of the nano-column 3 changes concentrically from the center C toward the outer periphery x. As shown in FIG. 6(b), the size of the nano-column may linearly decrease from the center C toward the outer periphery X. On the other hand, although not shown in drawings, the size of the nano-column may decrease in a curved manner (for example, in a n-function manner) from the center C toward the outer periphery x.

FIG. 6(c) shows the nano-column 3 in the vicinity of the center of the pixel, and FIG. 6(d) shows the nano-column 3 in the vicinity of the outer periphery of the pixel. The size of the nano-column in the center of the pixel is S₃, and the size of the nano-column in the outer periphery of the pixel is S₄. The “nano-column in the center of the pixel” and the “nano-column in the outer periphery of the pixel” are as described above.

S₃ is, for example, 100 nm or more, may be 150 nm or more, and may be 200 nm or more. Meanwhile, S₃ is, for example, 1000 nm or less, may be 500 nm or less, and may be 400 nm or less. Further, S₄ is not particularly limited as long as it is smaller than S₃, but may be, for example, 10 nm or more, may be 100 nm or more, and may be 150 nm or more. Meanwhile, S₄ is, for example, 300 nm or less, and may be 250 nm or less. Also, the ratio of S₄ to S₃ (S₄ S₃) is, for example, 0.4 or more and 0.8 or less, and may be 0.45 or more and 0.6 or less.

Also, in the present disclosure, the size of the nano-column may decrease in a stepwise manner from the center of the pixel toward the outer periphery of the pixel. In this case, the size of the nano-column may decrease in two or more stages, may decrease in five or more stages, or may decrease in ten or more stages, from the center of the pixel toward the outer periphery of the pixel.

In the direction from the center of the pixel toward the outer periphery of the pixel, the difference in size between adjacent nano-columns is, for example, 5 nm or less, may be 3 nm or less, or may be 1 nm or less. When the distance from the center of the pixel to the outer periphery of the pixel is L, in the region from the center of the pixel up to ½ L, the difference in size between adjacent nano-columns may be within the above range. Similarly, in the region from the center of the pixel up to ¾ L, the difference in size between adjacent nano-columns may be within the above range. When the size of the nano-column continuously changes from the center of the pixel toward the outer periphery of the pixel, the difference in size between adjacent nano-columns is usually larger than 0.

Although the arrangement of the nano-columns is not particularly limited, for example, it may be arranged in a triangular lattice shape or may be arranged in a square lattice shape. In FIG. 2 described above, the opening 2x of the mask layer 2 is arranged in a triangular lattice shape, and the nano-column 3 growing from the opening 2x is also arranged in a triangular lattice shape. Further, as shown in FIG. 5(c), the distance between the centers of adjacent nano-columns is referred to as a pitch. The pitch is, for example, 200 nm or more and may be 300 nm or more. Meanwhile, the pitch is, for example, 600 nm or less, and may be 500 nm or less. Further, the adjacent nano-columns are usually arranged so as not to be in contact with each other.

The gap between adjacent nano-columns is preferably, for example, 1 nm or more. The pitch of the nano-column in the pixel may be the same or different. The same pitch means that the difference between the maximum value and the minimum value of the pitch of the nano-column in the pixel is 5 nm or less. On the other hand, when the pitch is different, the difference between the maximum value and the minimum value of the pitch of the nano-column in the pixel is larger than 5 nm.

The plan view shape of the pixel in the present disclosure is not particularly limited, and examples thereof include a polygonal shape such as a triangular shape, a quadrangular shape (such as a square shape, a rectangular shape, and a rhombic shape), and a hexagonal shape. The size of the pixel is, for example, 10 μm or more, and may be 50 μm or more. Meanwhile, the size of the pixel is, for example, 500 μm or less, and may be 100 μm or less. In the present disclosure, the “size of a pixel” refers to a length of a straight line passing through a center of gravity (center) of a plan view shape in which a pixel is viewed in a plan view along a thickness direction and having a longest distance between intersections among straight lines intersecting the pixel at two points.

### 2. Nano-Column

The nano-column in the present disclosure extends in the thickness direction from the semiconductor substrate through the opening of the mask layer, and is a columnar crystal of the group-III nitride semiconductor. The nano-column may be configured by a single crystal of a group-III nitride semiconductor. It is preferable that the crystal defects in the nano-columns are little.

The group-III nitride semiconductor contains a group-III element and a N element. Typical examples of the group-III nitride semiconductor include gallium nitride (GaN). Also, other examples of the group-III nitride semiconductor include materials represented by the general formula: AlₓGa_{y}In_{1-x-y}N (0≤x≤1, 0≤y≤1, and 0≤x+y≤1). The x may be greater than 0. The x may be less than 1. The y may be greater than 0. The y may be less than 1. The x+y may be greater than 0 and less than 1. In the group-III nitride semiconductor represented by the general formula, the band gap at a room temperature is preferably 0.63 eV or more and 6.2 eV or less. Further, other examples of the group-III nitride semiconductor include boron nitride. Furthermore, From the viewpoint of manufacturing stability, the group-III nitride semiconductor is preferably a material having a hexagonal crystal structure.

The nano-column may include a columnar portion and a facet structure portion located on a distal end side of the columnar portion (opposite side to the semiconductor substrate). The facet structure portion refers to a polyhedral structure having, as a side surface, a facet surface located obliquely with respect to a direction perpendicular to the thickness direction. The shape of the columnar portion is not particularly limited, and examples thereof include a columnar shape, a quadrangular prism shape, and a hexagonal prism shape.

For example, in a case where a group-III nitride semiconductor having a wurtzite-type crystal structure is grown in a direction of a c-plane (=(0001) plane, a polar plane) to form a nano-column, a plan view shape of the nano-column becomes a hexagonal shape as shown in FIG. 2(b). FIGS. 7(a) and (b) are schematic cross-sectional views showing a cross section when the nano-column is cut along the central axis. Each of the nano-columns 3 illustrated in FIGS. 7(a) and (b) includes a columnar portion 3a and a facet structure portion 3b located on a distal end side of the columnar portion 3a (opposite side to the semiconductor substrate).

The facet structure portion 3b illustrated in FIG. 7(a) includes a facet surface 31 (a semipolar surface of a wurtzite-type crystal structure), and the shape thereof is a hexagonal pyramid shape. Examples of the semipolar surface include (10-1-1) plane, (10-1-3) plane, (11-22) plane, (11-24) plane, and (10-12) plane. On the other hand, the facet structure portion 3b illustrated in FIG. 7(b) includes a facet surface 31 (a semipolar surface of a wurtzite-type crystal structure), and further includes a flat surface 32 (a polar surface of a wurtzite-type crystal structure) parallel to a direction perpendicular to the thickness direction. Depending on the crystal growth condition, for example, the facet structure shown in FIG. 7(a) or FIG. 7(b) is formed.

When the size of the nano-column is small, the facet structure portion having the hexagonal pyramid shape shown in FIG. 7(a) is likely to be formed, and when the size of the nano-column is large, the facet structure portion as shown in FIG. 7(b) is likely to be formed. Depending on the growth condition of the crystal, when the size of the nano-column is set to about 300 nm or more, a flat surface (polar surface) as shown in FIG. 7(b) is likely to appear. In addition, as the size of the nano-column increases exceeding about 300 nm, the area of the flat surface (polar surface) tends to increase.

The height of the nano-column is not particularly limited, but may be, for example, 200 nm or more and may be 500 nm or more. Meanwhile, the height of the nano-column is, for example, 5 μm or less. The height of the nano-column refers to the distance from the surface of the mask layer 2 opposite to the semiconductor substrate to the tip of the nano-column (distance in the thickness direction).

### 3. Light-Emitting Layer

The light-emitting layer in the present disclosure is disposed at the tip of the nano-column. That is, the light-emitting layer is disposed on a surface opposite to the semiconductor substrate. The light-emitting layer is preferably provided so as to cover the facet structure portion of the nano-column.

The light-emitting layer preferably has a multiple quantum well (MQW) structure or a single quantum well (SQW) structure. The quantum well structure refers to a structure including a quantum well layer and a barrier layer sandwiching the quantum well layer. The band gap of the barrier layer is usually larger than the band gap of the quantum well layer. Examples of the light-emitting layer include InGaN, GaN, AlGaN, AlInGaN, InGaAsN, and InN. More specifically, the light-emitting layer is, for example, InGaN/GaN (barrier layer: InGaN, well layer: GaN), InₓGa₁₋ₓN/In_{y}Ga_{1-y}N (0≤x≤1, 0≤y≤1), GaN/AlGAN (barrier layer: AlGAN, well layer: GaN), and AlₓGa₁₋ₓN/Al_{y}Ga_{1-y}N (0≤x≤1, 0≤y≤1).

The peak wavelength of the light emitted from the light-emitting layer depends on the size of the nano-column immediately before the light-emitting layer is formed. Specifically, the peak wavelength of the light emitted from the light-emitting layer is shifted to the longer wavelength side as the size of the nano-column is larger, and is shifted to the shorter wavelength side as the size of the nano-column is smaller. That is, the peak wavelength of the light emitted from the light-emitting layer can be controlled based on the size of the nano-column. The size of the nano-column can be controlled based on the size of the opening in the mask layer.

The peak wavelength of the light emitted from the light-emitting layer depends on the surface area of the facet structure portion of the nano-column. Specifically, the peak wavelength of the light emitted from the light-emitting layer is shifted to the longer wavelength side as the surface area of the facet structure portion is larger, and is shifted to the shorter wavelength side as the surface area of the facet structure portion is smaller. That is, the peak wavelength of the light emitted from the light-emitting layer can be controlled based on the surface area of the facet structure portion of the nano-column.

### 4. Covering Semiconductor Layer

The covering semiconductor layer in the present disclosure covers the light-emitting layer, and is a layer including a semiconductor. The covering semiconductor layer preferably includes a crystal of a semiconductor, and more preferably includes a crystal of a group-III nitride semiconductor. The covering semiconductor layer may be configured by a single crystal of a group-III nitride semiconductor. It is preferable that the crystal defects in the covering semiconductor layer are little. Since the group-III nitride semiconductor is in the same contents as those described in “2. Nano-column” above, the descriptions thereof is omitted here.

The covering semiconductor layer 5 only needs to cover at least a part of the light-emitting layer 4. In particular, the covering semiconductor layer 5 preferably covers the light-emitting layer 4 so as to encompass the entire circumference of the light-emitting layer 4 in a plan view along the thickness direction. This is because better optical characteristics can be obtained. Also, as shown in FIG. 1, the covering semiconductor layer 5 may completely cover the light-emitting layer 4. That is, the covering semiconductor layer 5 may cover the light-emitting layer 4 so that the light-emitting layer 4 does not have an exposed portion to the external space. By suppressing the formation of the non-light-emitting recombination level caused by the exposed portion, high internal quantum efficiency is achieved.

In addition, the conductivity type of the nano-columns and the conductivity type of the covering semiconductor layer are usually in the opposite relationship. When the conductivity type of the nano-column is n-type, the conductivity type of the covering semiconductor layer is usually p-type. In this case, the electrons supplied from the nano-columns and the holes supplied from the covering semiconductor layer are coupled to each other, so that the light-emitting layer emits light. On the other hand, when the conductivity type of the nano-column is p-type, the conductivity type of the covering semiconductor layer is usually n-type.

### 5. Semiconductor Substrate

The semiconductor substrate in the present disclosure supports the nano-column. Also, the semiconductor substrate includes, for example, a base substrate and a semiconductor layer. Examples of the base substrate include a sapphire substrate, a silicon substrate, and a Sic substrate.

The semiconductor layer preferably includes a group-III nitride semiconductor as a semiconductor. The semiconductor layer may be configured by a single crystal of a group-III nitride semiconductor. It is preferable that the crystal defects in the semiconductor layer are little. The group-III nitride semiconductor is in the same contents as those described in “2. Nano-column” above. The group-III nitride semiconductor in the semiconductor layer and the group-III nitride semiconductor in the nano-column may have the same composition.

As shown in FIG. 1, the semiconductor layer 1b may include a concave portion 1x at least at a position overlapping the opening 2x of the mask layer 2 in a plan view along the thickness direction Dr. The depth of the concave portion 1x is not particularly limited, but is, for example, 1 nm or more and 250 nm or less.

A buffer layer may be disposed between the base substrate and the semiconductor layer. By providing the buffer layer, the crystal quality of the semiconductor layer (such as the flatness of the layer surface) is improved. Examples of the buffer layer include a group-III nitride semiconductor such as gallium nitride and aluminum nitride. In addition, the semiconductor substrate may not include a base substrate. That is, the semiconductor substrate may be a self-standing semiconductor layer (such as a GaN substrate).

### 6. Mask Layer

The mask layer in the present disclosure includes an opening. Examples of the plan view shape of the opening include a square shape, a circular shape, and a polygonal shape. The shape of the opening in a plan view is preferably axisymmetric. By adjusting the pattern of the opening, the density of the nano-column can be controlled. Similarly, by adjusting the size of the opening, the size of the nano-column can be controlled. The pattern and the size of the opening are adjusted so that the above-described nano-columns are obtained.

The mask layer is preferably a metal mask layer including a metal. Examples of the metal element included in the metal mask layer include titanium (Ti), tantalum (Ta), iron (Fe), nickel (Ni), platinum (Pt), gold (Au), cobalt (Co), tungsten (W), and molybdenum (Mo). The metal mask layer may contain only one metal element, or may contain two or more metal elements. The metal mask layer preferably contains at least Ti. The metal mask layer may be a layer including an oxide on the surface, or may be a metal oxide layer. The thickness of the mask layer is not particularly limited, but is, for example, 2 nm or more and 100 nm or less.

### 7. Semiconductor Optical Element Array

In the semiconductor optical element array in the present disclosure, all of the pixels may be light-emitting regions, and some of the pixels may be light-emitting regions. For example, a part of the pixel P illustrated in FIG. 8 is the light-emitting region a.

The light-emitting region a preferably includes the center C of the pixel P. Examples of the plan view shape of the light-emitting region include a square shape, a circular shape, and a polygonal shape. The shape of the light-emitting region in a plan view may be axisymmetric. In addition, the shape of the light-emitting region in a plan view may be similar or not similar to the pixel.

The size of the light-emitting region may be, for example, 5 μm or more and may be 50 μm or more. Meanwhile, the size of the light-emitting region is, for example, 300 μm or less, and may be 100 μm or less. In the present disclosure, the “size of the light-emitting region” refers to the length of the straight line passing through the center of gravity point (center) of the plan view shape in a plan view along the thickness direction of the light-emitting region and having the longest distance between the intersection points among the straight lines intersecting the light-emitting region at two points.

When a part of the pixel is the light-emitting region, the area ratio of the light-emitting region occupied in the pixel is, for example, 5% or more and may be 10% or more. Meanwhile, the area ratio is, for example, 80% or less and may be 60% or less. A method of forming the light-emitting region includes, for example, a method of adjusting the shape of an electrode electrically connected to the covering semiconductor layer.

The emission spectrum in the light-emitting region may have a peak wavelength at a position of, for example, 430 nm or more and less than 500 nm. In this case, blue light emission is obtained. The peak wavelength refers to a wavelength at which the highest emission intensity is obtained in the emission spectrum. Also, the emission spectrum in the light-emitting region may have a peak wavelength at a position of, for example, 500 nm or more and less than 580 nm. In this case, green light emission is obtained. The emission spectrum in the light-emitting region may have a peak wavelength at a position of, for example, 580 nm or more and less than 780 nm. In this case, red light emission is obtained.

In the emission spectrum in the light-emitting region, the number of peaks observed in the visible light region of 380 nm or more and 780 nm or less is preferably 2 or less, and more preferably 1. When the number of peaks observed in the visible light region of 380 nm or more and 780 nm or less is 2 or more, the highest emission intensity is preferably twice or more of the second highest emission intensity, and more preferably 4 times or more.

In addition, a light-emitting region in which the size of all the nano-columns in the light-emitting region is changed to the size of the nano-column in the center of the pixel is defined as a comparison light-emitting region. In this case, it is preferable that the emission intensity of the peak wavelength in the light-emitting region is larger than the emission intensity of the peak wavelength in the comparison light-emitting region.

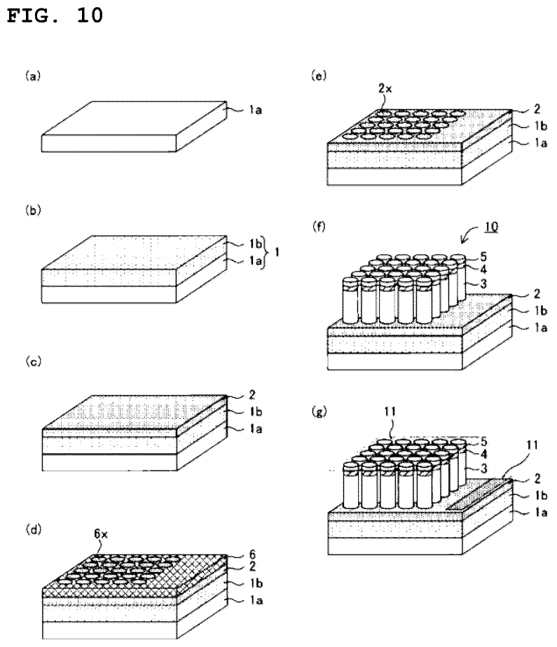

The semiconductor optical element array in the present disclosure preferably includes a plurality of pixels. For example, as shown in FIG. 9, the semiconductor optical element array preferably includes a plurality of pixels (P₁, P₂, P₃). The light emission characteristics of the nano-columns in the present disclosure vary depending on the size thereof. Therefore, for example, by adjusting the size of the nano-columns, the pixels P₁, P₂, and P₃ can be pixels that emit light having wavelengths of three primary colors of R (red), G (green), and B (blue), respectively.

The use application of the semiconductor optical element array in the present disclosure is not particularly limited. Examples of the use application of the semiconductor optical element array include light-emitting elements such as light-emitting diodes and laser diodes.

The method for producing the semiconductor optical element array in the present disclosure is not particularly limited. FIG. 10 is a schematic perspective view illustrating an example of a method for producing the semiconductor optical element array in the present disclosure. In the method for producing the semiconductor optical element array illustrated in FIG. 10, first, the base substrate 1a is prepared (FIG. 10(a) ). Next, by the MOCVD method or the MBE method, a buffer layer (not shown in drawing) including a group-III nitride semiconductor is formed on the base substrate 1a under a low temperature condition, a crystal of the group-III nitride semiconductor is grown on the buffer layer in a high temperature state, and the semiconductor layer 1b is formed (FIG. 10(b) ). As a result, the semiconductor substrate 1 including the base substrate 1a and the semiconductor layer 1b is obtained.

After that, a mask layer 2 containing titanium (Ti) is formed on the main surface of the semiconductor layer 1b by a vacuum deposition method (FIG. 10(c) ). Next, a resist layer 6 is formed on the mask layer 2, electron beam drawing and development are performed, and an opening 6x is formed (FIG. 10(d) ). At this time, the drawing pattern of the opening 6x is set so as to obtain the above-described pixel. Next, the mask layer 2 exposed from the opening 6x is removed by etching to form the opening 2x (FIG. 10(e) ). At this time, when not only the mask layer 2 but also the semiconductor layer 1b are etched, a concave portion 1x as shown in FIG. 1 is formed.

After that, the crystal of the group-III nitride semiconductor is grown from the semiconductor layer 1b through the opening 2x by the MOCVD method or the MBE method. Thereby, the nano-column 3 is formed (FIG. 10 (f) ). At this time, the light-emitting layer 4 and the covering semiconductor layer 5 may be continuously formed. For example, when a nano-column is formed using the MBE method, a raw material gas containing active nitrogen generated by high-frequency plasma excitation and a group-III metal is introduced onto the semiconductor layer to grow a crystal of the group-III nitride semiconductor. The crystal growth temperature is, for example, 350 °C or more and 1200 °C or less. For example, when a GaN crystal is grown, the crystal growth temperature is preferably 400 °C or more and 1000 °C or less. In addition, when the crystal of the group-III nitride semiconductor grows, it may grow in the thickness direction and also grow in a direction (in-plane direction) orthogonal to the thickness direction. In that case, as shown in FIG. 1, the size of the nano-column 3 is usually larger than the size of the opening 2x and the size of the concave portion 1x. In this way, as shown in FIG. 10(f), the semiconductor optical element array 10 is obtained. After that, as shown in FIG. 10(g), the electrode 11 may be disposed on each of the covering semiconductor layer 5 and the mask layer 2.

The present disclosure is not limited to the above-described embodiment. The above-described embodiments are examples, and those having substantially the same configuration as the technical idea described in the claims of the present disclosure and exhibiting similar functions and effects are included in the technical scope of the present disclosure.

### EXAMPLES

### Comparative Example 1

GaN was grown on the (0001) plane of a sapphire substrate (base substrate) by the MOCVD method to form a GaN layer (semiconductor layer, thickness: about 3.5 μm). Next, a titanium thin film (mask layer, thickness: about 5 nm) was formed on the GaN layer by a vacuum deposition method. Next, a resist layer was formed on the titanium thin film, electron beam drawing was performed, and development was performed to form a resist pattern including an opening. Next, the mask layer exposed from the opening of the resist pattern was removed by etching, and a patterned opening was formed in the mask layer. Next, the resist pattern was peeled off.

After that, the GaN columnar crystal was grown from the semiconductor substrate through the opening of the mask layer under a temperature condition of 900 °C by an RF MBE method to form a nano-column (height: 2.5 μm). As a result, the pixels shown in FIG. 11 (a) and below were obtained.
Plan view shape of pixel: hexagonal shape
Pixel size: 150 μm
Pitch between centers of adjacent nano-columns: 350 nm
Size of nano-column in center of pixel: 60 nm
Size of nano-column in outer periphery of pixel: 60 nm

Subsequently, a light-emitting layer having a multiple quantum well structure including an InGaN film (thickness: 1 nm) was formed at the tip of the nano-column. Subsequently, a GaN crystal was grown on the light-emitting layer to form a covering semiconductor layer (thickness: 10 nm). Thereby, a semiconductor optical element array was obtained.

In addition, the nano-column was observed with a scanning electron microscope (SEM) at a stage where the same operation as described above was performed and the nano-column was formed. The results are shown in FIG. 11(b) and FIG. 11(c).

As shown in FIG. 11(b) and FIG. 11(c), the size of the nano-column in the center of the pixel and the size of the nano-column in the outer periphery of the pixel were the same.

### Example 1

A semiconductor optical element array was obtained in the same manner as in Comparative Example 1 except that the pixels shown in FIG. 11 (d) and below were formed.
Plan view shape of pixel: hexagonal shape
Pixel size (maximum length between opposing corners): 150 μm
Pitch between centers of adjacent nano-columns: 350 nm
Size of nano-column in center of pixel: 60 nm
Size of nano-column in outer periphery of pixel: 100 nm

The results of SEM observation of the nano-columns are shown in FIG. 11(e) and FIG. 11(f). As shown in FIG. 11(e) and FIG. 11(f), in the pixel, the size of the nano-column continuously increased from the center toward the outer periphery.

### Example 2

A semiconductor optical element array was obtained in the same manner as in Comparative Example 1 except that the pixels shown in FIG. 11 (g) and below were formed.
Plan view shape of pixel: hexagonal shape
Pixel size (maximum length between opposing corners): 150 μm
Pitch between centers of adjacent nano-columns: 350 nm Size of nano-column in center of pixel: 60 nm
Size of nano-column in outer periphery of pixel: 350 nm

The results of SEM observation of the nano-columns are shown in FIG. 11(h) and FIG. 11(i). As shown in FIG. 11(h) and FIG. 11(i), in the pixels, the size of the nano-columns continuously increased from the center toward the outer periphery.

### Evaluation

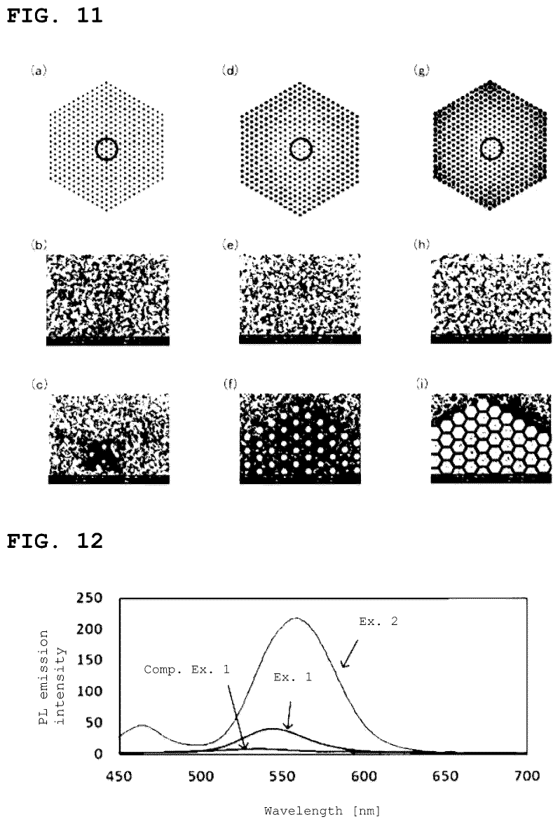

The same operations as in Comparative Example 1 and Examples 1 and 2 were performed, and at the stage where the light-emitting layer was formed, laser irradiation was performed to the light-emitting layer, and the emission intensity was measured. As indicated by black circles in FIGS. 11 (a), (d), and (g), the measurement region was a region having a diameter of 30 μm including the center of the pixel. The results are shown in FIG. 12. As shown in FIG. 12, in Examples 1 and 2, a light emission intensity higher than that in Comparative Example 1 was obtained. More specifically, it was confirmed that high emission intensity can be obtained without increasing the size of the nano-column in the measurement region by increasing the size of the nano-column around the measurement region.

Also, in Example 1, the size of the nano-column in the center of the measurement region was 50 nm, and the size of the nano-column in the outer periphery of the measurement region was 60 nm. Comparing the areas of the nano-columns occupied in the measurement region, Example 1 became 1.21 times as compared with Comparative Example 1. In Example 2, the size of the nano-column in the center of the measurement region was 50 nm, and the size of the nano-column in the outer periphery of the measurement region was 100 nm. Comparing the areas of the nano-columns occupied in the measurement region, Example 2 became 2.25 times as compared with Comparative Example 1. Since these increase rates are smaller than the increase amount of the emission intensity shown in FIG. 12, it was confirmed in Examples 1 and 2 that the emission intensity was improved due to factors other than the increase in area.

Further, when the half-value width of the peak shown in FIG. 12 was measured, Comparative Example 1 was 82 nm, Example 1 was 47.6 nm, and Example 2 was 55.4 nm. In Examples 1 and 2, since the size of the nano-column was changed even in the region of the measurement region, an increase in the half-value width (reduction in monochromaticity) was expected, but it was surprisingly confirmed that the half-value width was reduced (monochromaticity was improved).

### Comparative Example 2

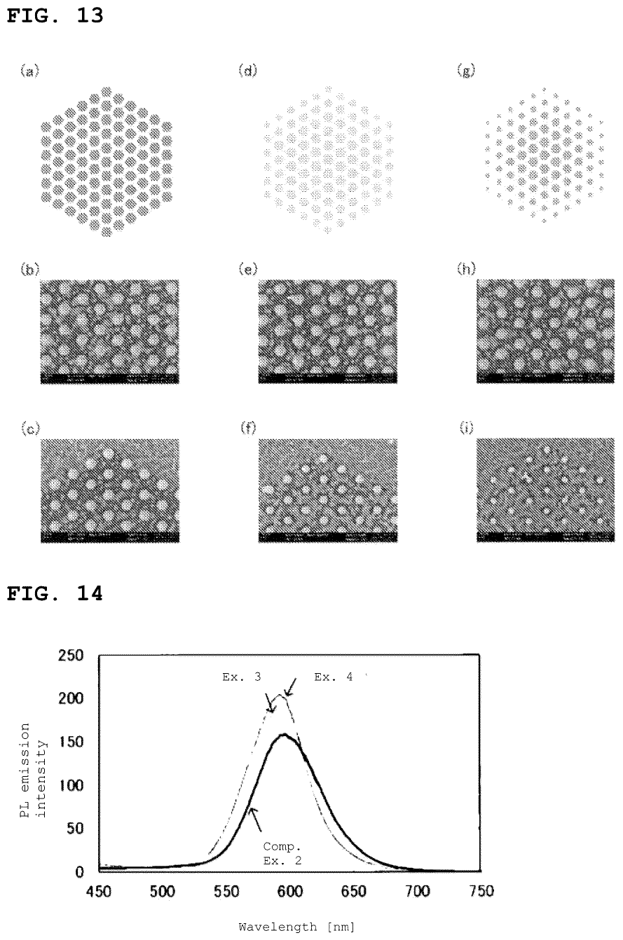

A semiconductor optical element array was obtained in the Same manner as in Comparative Example 1 except that the pixels shown in FIG. 13(a) and below were formed.
Plan view shape of pixel: hexagonal shape
Pixel size (maximum length between opposing corners): 150 μm
Pitch between centers of adjacent nano-columns: 450 nm
Size of nano-column in center of pixel: 200 nm
Size of the nano-column in outer periphery of pixel: 200 nm

The results of SEM observation of the nano-columns are shown in FIGS. 13 (b) and 13 (c). As shown in FIG. 13B and FIG. 13C, the size of the nano-column in the center of the pixel and the size of the nano-column in the outer periphery of the pixel were the same.

### Example 3

A semiconductor optical element array was obtained in the same manner as in Comparative Example 1 except that the pixels shown in FIG. 13D and below were formed.
Plan view shape of pixel: hexagonal shape
Pixel size (maximum length between opposing corners): 150 μm
Pitch between centers of adjacent nano-columns: 450 nm
Size of nano-column in center of pixel: 200 nm
Size of nano-column in outer periphery of pixel: 150 nm

The results of SEM observation of the nano-columns are shown in FIG. 13(e) and FIG. 13(f). As shown in FIG. 13(e) and FIG. 13(f), in the pixels, the size of the nano-columns continuously decreased from the center toward the outer periphery.

### Example 4

A semiconductor optical element array was obtained in the same manner as in Comparative Example 1 except that the pixels shown in FIG. 13 (g) and below were formed.
Plan view shape of pixel: hexagonal shape
Pixel size (maximum length between opposing corners): 150 μm
Pitch between centers of adjacent nano-columns: 450 nm
Size of nano-column in center of pixel: 200 nm
Size of nano-column in outer periphery of pixel: 100 nm

The results of SEM observation of the nano-columns are shown in FIG. 13(h) and FIG. 13(i). As shown in FIG. 13(h) and FIG. 13(i), in the pixels, the size of the nano-columns continuously decreased from the center toward the outer periphery.

### Evaluation

The same operations as in Comparative Example 2 and Examples 3 and 4 were performed, laser irradiation was performed to the light-emitting layer at the stage where the light-emitting layer was formed, and the emission intensity was measured in the same manner as described above. The results are shown in FIG. 14. As shown in FIG. 14, in Examples 3 and 4, higher emission intensity was obtained as compared with Comparative Example 2. When the half-value width of the peak shown in FIG. 14 was measured, Comparative Example 2 was 61.2 nm, Example 3 was 57.5 nm, and Example 4 was 53.9 nm.

As described above, in the present disclosure, for example, the following inventions are provided.
[1]

A semiconductor optical element array comprising:
a semiconductor substrate,
a mask layer disposed on a main surface of the semiconductor substrate and including an opening,
a nano-column that extends in a thickness direction from the semiconductor substrate through the opening, and is a columnar crystal of a group-III nitride semiconductor,
a light-emitting layer disposed at a tip of the nano-column, and
a covering semiconductor layer covering the light-emitting layer and including a semiconductor, wherein
the semiconductor optical element array includes a pixel including a plurality of the nano-columns; and
in the pixel, a size of the nano-column either increases in a stepwise manner or continuously, or decreases in a stepwise manner or continuously, from center toward outer periphery.
[2]

The semiconductor optical element array according to [1], wherein a size of the nano-column in the center of the pixel is 10 nm or more and 1000 nm or less.
[3]

The semiconductor optical element array according to [1] or [2], wherein in the pixel, the size of the nano-column increases in a stepwise manner or continuously from center toward outer periphery.
[4]

The semiconductor optical element array according to [3], wherein, when the size of the nano-column in the center of the pixel is S₁ [nm] and the size of the nano-column in the outer periphery of the pixel is S₂ [mm], a ratio of the S₂ to the S₁ (S₂/S₁) is 1.5 or more and 6.0 or less.
[5]

The semiconductor optical element array according to [1] or [2], wherein, in the pixel, the size of the nano-column decreases in a stepwise manner or continuously from center toward outer periphery.
[6]

The semiconductor optical element array according to [5], wherein when the size of the nano-column in the center of the pixel is S₃ [nm] and the size of the nano-column in the outer periphery of the pixel is S₄ [nm], the ratio of the S₄ to the S₃ (S₄/S₃) is 0.4 or more and 0.8 or less.
[7]

The semiconductor optical element array according to any one of [1] to [6], wherein, in a direction from the center toward the outer periphery, a difference in size between adjacent the nano-columns is 5 nm or less.
[8]

The semiconductor optical element array according to any one of [1] to [7], wherein the nano-column is a columnar crystal of GaN.
[9]

The semiconductor optical element array according to any one of [1] to [8], wherein the light-emitting layer includes InGaN.

The semiconductor optical element array according to any one of [1] to [9], wherein a part of the pixel is a light-emitting region, and the light-emitting region includes the center.

### REFERENCE SIGNS LIST

1 . . . semiconductor substrate
1a . . . base substrate
1b . . . semiconductor layer
2 . . . mask layer
3 . . . nano-column
4 . . . light-emitting layer
5 . . . covering semiconductor layer
10 . . . semiconductor optical element array

1. A semiconductor optical element array comprising:
a semiconductor substrate,
a mask layer disposed on a main surface of the semiconductor substrate and including an opening,
a nano-column that extends in a thickness direction from the semiconductor substrate through the opening, and is a columnar crystal of a group-III nitride semiconductor,
a light-emitting layer disposed at a tip of the nano-column, and
a covering semiconductor layer covering the light-emitting layer and including a semiconductor, wherein
the semiconductor optical element array includes a pixel including a plurality of the nano-columns; and
in the pixel, a size of the nano-column either increases in a stepwise manner or continuously, or decreases in a stepwise manner or continuously, from center toward outer periphery.

2. The semiconductor optical element array according to claim 1, wherein a size of the nano-column in the center of the pixel is 10 nm or more and 1000 nm or less.

3. The semiconductor optical element array according to claim 1, wherein in the pixel, the size of the nano-column increases in a stepwise manner or continuously from center toward outer periphery.

4. The semiconductor optical element array according to claim 3, wherein, when the size of the nano-column in the center of the pixel is S₁ [nm] and the size of the nano-column in the outer periphery of the pixel is S₂ [nm], a ratio of the S₂ to the S₁ (S₂/S₁) is 1.5 or more and 6.0 or less.

5. The semiconductor optical element array according to claim 1, wherein, in the pixel, the size of the nano-column decreases in a stepwise manner or continuously from center toward outer periphery.

6. The semiconductor optical element array according to claim 5, wherein when the size of the nano-column in the center of the pixel is S₃ [nm] and the size of the nano-column in the outer periphery of the pixel is S₄ [nm], the ratio of the S₄ to the S₃ (S₄/S₃) is 0.4 or more and 0.8 or less.

7. The semiconductor optical element array according to claim 1, wherein, in a direction from the center toward the outer periphery, a difference in size between adjacent the nano-columns is 5 nm or less.

8. The semiconductor optical element array according to claim 1, wherein the nano-column is a columnar crystal of GaN.

9. The semiconductor optical element array according to claim 1, wherein the light-emitting layer includes InGaN.

10. The semiconductor optical element array according to claim 1, wherein a part of the pixel is a light-emitting region, and the light-emitting region includes the center.
